(19) United States
(12) Patent Application Publication
(10) Pub. No.: US 2026/0173967 A1
(43) Pub. Date: Jun. 18, 2026

(54) SEMICONDUCTOR PACKAGE

(71) Applicant: Samsung Electronics Co., Ltd., Suwon-si (KR)

(72) Inventors: Ji Hwan KIM, Suwon-si (KR); Han Sol YOO, Suwon-si (KR)

(73) Assignee: Samsung Electronics Co., Ltd., Suwon-si (KR)

(21) Appl. No.: 19/347,839

(22) Filed: Oct. 2, 2025

(30) Foreign Application Priority Data
Dec. 13, 2024 (KR) 10-2024-0185614

(51) Int. Cl. H01L 23/00; H01L 25/065

(52) U.S. Cl. CPC H10W 90/00; H10W 72/30; H10W 72/387; H10W 72/5473; H10W 72/865; H10W 72/884; H10W 90/20; H10W 90/28; H10W 90/732; H10W 90/734; H10W 90/752; H10W 90/754

(57) ABSTRACT

A semiconductor package including a package substrate; a first semiconductor chip on the package substrate; a second semiconductor chip on the first semiconductor chip; and an adhesive layer between the first semiconductor chip and the second semiconductor chip. The first semiconductor chip includes a plurality of redistribution patterns on a first surface of the first semiconductor chip, a plurality of chip connecting pads, and an insulating layer enclosing the plurality of redistribution patterns and the plurality of chip connecting pads. The insulating layer defines at least one trench therein between the plurality of redistribution patterns and the plurality of chip connecting pads, the plurality of redistribution patterns are adjacent to the plurality of chip connecting pads, and the plurality of chip connecting pads are electrically connected to the second semiconductor chip through wires.

### CROSS-REFERENCE TO RELATED APPLICATION

This application claims priority from Korean Patent Application No. 10-2024-0185614 filed on Dec. 13, 2024, in the Korean Intellectual Property Office and all the benefits accruing therefrom under 35 U.S.C. 119, the contents of which in its entirety are herein incorporated by reference.

### BACKGROUND

The present disclosure relates to semiconductor packages.

When attaching semiconductor dies stacked vertically, an adhesive material is used between the dies.

An adhesive material having low viscosity is applied to reduce (and/or minimize) a void between the adhesive materials when bonding the dies. However, low viscosity may cause the adhesive material to overflow beyond a bonding part of a semiconductor die or the adhesive material to spread excessively when a pressure is applied to the semiconductor die. Such a bleeding-out phenomenon of the adhesive material may contaminate a chip connecting pad. Therefore, there is a desire for a semiconductor package that may limit and/or prevent contamination of the chip connecting pad while reducing (and/or minimizing) void formation in or at adhesive material.

### SUMMARY

Some example embodiments of the inventive concepts provide a semiconductor package having improved reliability.

However, some other example embodiments of the inventive concepts are not limited to some example embodiments set forth herein. The above and other example embodiments of the inventive concepts will become more apparent to one of ordinary skill in the art to which the inventive concepts pertain by referencing the detailed description of the inventive concepts given below.

Some example embodiments provide a semiconductor package that includes a package substrate; a first semiconductor chip on the package substrate; a second semiconductor chip on the first semiconductor chip; and an adhesive layer between the first semiconductor chip and the second semiconductor chip. The first semiconductor chip includes a plurality of redistribution patterns on a first surface of the first semiconductor chip, a plurality of chip connecting pads, and an insulating layer enclosing the plurality of redistribution patterns and the plurality of chip connecting pads. The insulating layer defines at least one trench therein between the plurality of redistribution patterns and the plurality of chip connecting pads, the plurality of redistribution patterns are adjacent to the plurality of chip connecting pads, and the plurality of chip connecting pads are electrically connected to the second semiconductor chip through wires.

Some example embodiments of the present disclosure further provide a semiconductor package that includes a package substrate; a first semiconductor chip on the package substrate; a second semiconductor chip on the first semiconductor chip; an adhesive layer between the first semiconductor chip and the second semiconductor chip; and a mold layer enclosing the package substrate, the first semiconductor chip, the second semiconductor chip, and the adhesive layer. The first semiconductor chip includes a plurality of redistribution patterns on a first surface of the first semiconductor chip, a plurality of chip connecting pads, and an insulating layer enclosing the plurality of redistribution patterns and the plurality of chip connecting pads, the plurality of chip connecting pads being electrically connected to the second semiconductor chip through wires. The insulating layer includes a first insulating layer enclosing side faces of the plurality of chip connecting pads, and a second insulating layer enclosing the plurality of redistribution patterns. The first insulating layer defines a trench therein between the plurality of chip connecting pads and the plurality of redistribution patterns,

the second insulating layer defines a redistribution trench between chip connecting pads of the plurality of chip connecting pads, and a depth of the trench is greater than a depth of the redistribution trench.

Some example embodiments of the present disclosure still further provide a semiconductor package that includes a package substrate; a first semiconductor chip on the package substrate; a second semiconductor chip on the first semiconductor chip; an adhesive layer between the first semiconductor chip and the second semiconductor chip; and a mold layer enclosing the package substrate, the first semiconductor chip, the second semiconductor chip, and the adhesive layer. The first semiconductor chip includes a plurality of redistribution patterns on a first surface of the first semiconductor chip, a plurality of chip connecting pads, and an insulating layer enclosing the plurality of redistribution patterns and the plurality of chip connecting pads, the plurality of chip connecting pads being electrically connected to the second semiconductor chip through wires. The insulating layer includes a first insulating layer enclosing side faces of the plurality of chip connecting pads, and a second insulating layer enclosing the plurality of redistribution patterns. The first insulating layer defines a trench between the plurality of chip connecting pads and the plurality of redistribution patterns, the second insulating layer defines a redistribution trench between chip connecting pads of the plurality of chip connecting pads, a depth of the trench is greater than a depth of the redistribution trench, and a length of the trench in a horizontal direction is greater than or equal to a length of the second semiconductor chip in the horizontal direction. The adhesive layer includes a first sub-adhesive layer overlapping the second semiconductor chip in a vertical direction, and a second sub-adhesive layer not overlapping the second semiconductor chip in the vertical direction. The first sub-adhesive layer and the second sub-adhesive layer are integral, and at least a part of the second sub-adhesive layer contacts the trench.

Some example embodiments of the present disclosure further provide a method of manufacturing a semiconductor package that includes forming a plurality of redistribution patterns on a first surface of a first semiconductor chip; forming a plurality of chip connecting pads on the first surface of the first semiconductor chip; forming an insulating layer enclosing the plurality of redistribution patterns and the plurality of chip connecting pads, the insulating layer defining at least one trench therein between the plurality of redistribution patterns and the plurality of chip connecting pads, and the plurality of redistribution patterns are adjacent to the plurality of chip connecting pads; attaching the first semiconductor chip on a package substrate; attaching a second semiconductor chip on the first semiconductor chip using an adhesive layer; and electrically connecting the plurality of chip connecting pads to the second semiconductor chip with wires.

In some example embodiments of the method of manufacturing the semiconductor package, a depth of the at least one trench is less than or equal to a height of the insulating layer.

In some example embodiments of the method of manufacturing the semiconductor package, the forming the plurality of redistribution patterns includes forming a redistribution pattern from among the plurality of redistribution patterns as including a first sub-redistribution pattern and a second sub-redistribution pattern adjacent to each other, and the insulating layer defines a redistribution trench therein between the first sub-redistribution pattern and the second sub-redistribution pattern.

In some example embodiments of the method of manufacturing the semiconductor package, a depth of the at least one trench is greater than a depth of the redistribution trench.

In some example embodiments of the method of manufacturing the semiconductor package, the forming the plurality of chip connecting pads includes forming a first sub-chip connecting pad and a second sub-chip connecting pad that are respectively at opposite ends of the plurality of redistribution patterns, and the at least one trench includes a first trench between the plurality of redistribution patterns and the first sub-chip connecting pad, and a second trench between the plurality of redistribution patterns and the second sub-chip connecting pad.

In some example embodiments of the method of manufacturing the semiconductor package, the forming the plurality of chip connecting pads includes forming a first chip connecting pad adjacent to a first corner of the first semiconductor chip; and forming a second chip connecting pad adjacent to a second corner of the first semiconductor chip opposite to the first corner, so that a length of the at least one trench in a horizontal direction is greater than or equal to a distance between the first chip connecting pad and the second chip connecting pad in the horizontal direction.

In some example embodiments, the method of manufacturing the semiconductor package further includes forming a mold layer enclosing the package substrate, the first semiconductor chip, the second semiconductor chip, and the adhesive layer.

### BRIEF DESCRIPTION OF THE DRAWINGS

The above and other aspects and features of the present disclosure will become more apparent by describing in detail some example embodiments thereof with reference to the attached drawings, in which:

FIG. 1 is a top view for explaining a semiconductor package according to some example embodiments of the inventive concepts.

FIG. 2 is a cross-sectional view showing a cross section taken along I-I′ of FIG. 1.

FIG. 3 is a top view showing only a partial configuration included in a region A of FIG. 2.

FIG. 4 is a cross-sectional view showing a cross section taken along II-II′ of FIG. 3.

FIGS. 5, 6 and 7 are enlarged views showing only a region B of FIG. 4 and a region D of FIG. 13 according to some example embodiments.

FIG. 8 is a top view showing only a partial configuration included in the region A of FIG. 2.

FIG. 9 is a top view for explaining only some configurations of FIG. 1, to explain a semiconductor package according to some example embodiments.

FIG. 10 is a top view for explaining a semiconductor package according to some example embodiments of the inventive concepts.

FIG. 11 is a cross-sectional view showing a cross section taken along III-III′ of FIG. 10.

FIG. 12 is a top view showing only a partial configuration included in the region C of FIG. 11.

FIG. 13 is a cross-sectional view showing a cross section taken along IV-IV′ of FIG. 12.

FIG. 14 is a top view showing only a partial configuration included in a region C of FIG. 11.

FIG. 15 is a top view for explaining only a partial configuration of FIG. 10, to explain the semiconductor package according to some example embodiments of the inventive concepts.

FIGS. 16 and 17 are top views for explaining a semiconductor package according to some example embodiments of the inventive concepts.

### DETAILED DESCRIPTION

Some example embodiments of the inventive concepts will be described below in detail with reference to the attached drawings. The same reference numerals are used for the same constituent elements in the drawings, and repeated description thereof will not be provided.

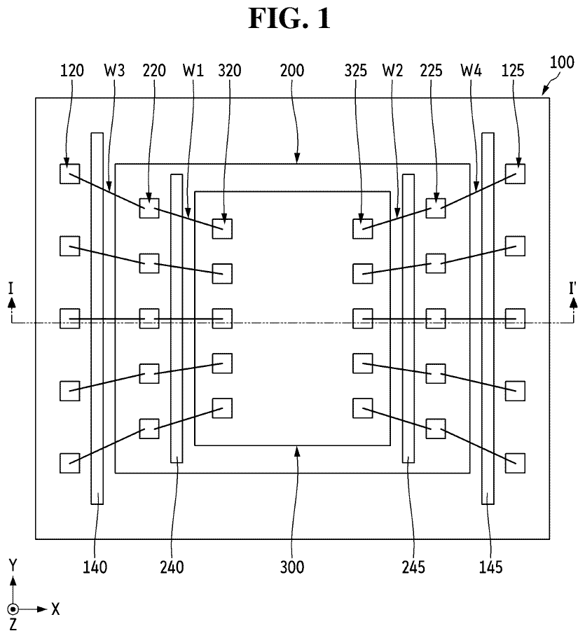

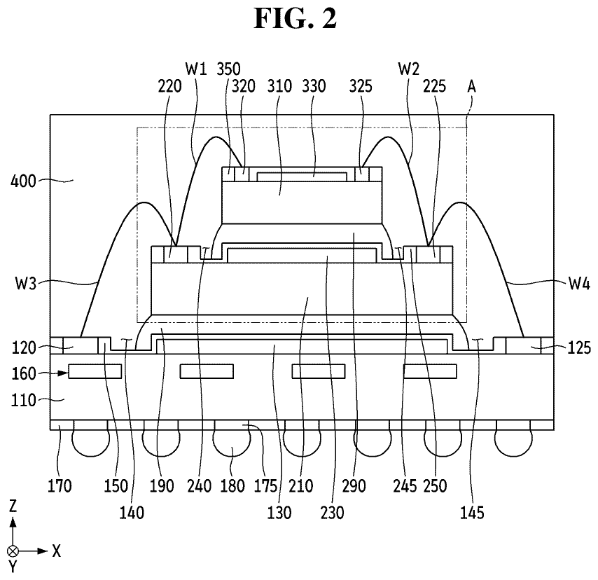

FIG. 1 is a top view for explaining a semiconductor package according to some example embodiments of the inventive concepts. FIG. 2 is a cross-sectional view showing a cross section taken along I-I′ of FIG. 1.

Referring to FIG. 1 and FIG. 2, in some example embodiments, the semiconductor package 1 may include a package substrate 100, a first semiconductor chip 200, a second semiconductor chip 300, and a mold layer 400. The first semiconductor chip 200 and the second semiconductor chip 300 may be stacked sequentially on the package substrate 100.

In some example embodiments, the first semiconductor chip 200 may be attached onto the package substrate 100 by a first adhesive layer 190. The second semiconductor chip 300 may be attached onto the first semiconductor chip 200 by a second adhesive layer 290. The first adhesive layer 190 and the second adhesive layer 290 may include, for example, an adhesive material such as a die attach film (DAF), an adhesive paste or an epoxy resin.

The size of the second semiconductor chip 300 may be smaller than that of the first semiconductor chip 200.

In some example embodiments, the package substrate 100 may include a first insulating film 150 formed on an upper side of the base substrate 110, and a second insulating film 170 formed on a lower side of the base substrate 110.

For example, the package substrate 110 may include a printed circuit board (PCB), a flexible substrate, a tape substrate, and the like. The printed circuit board may be a multi-layer circuit board having vias and various circuits therein.

The package substrate 100 may include an external connecting terminal 180 on the lower side of the base substrate 110, and a plurality of first chip connecting pads 120 and 125 and first redistribution patterns 130 and 160 on the upper side. Although the base substrate 110 is shown as being a single layer in the drawing, the base substrate 110 may be a plurality of layers stacked in a third direction (e.g., a Z or vertical direction).

The external connecting terminal 180 may be, for example, a solder ball. The first chip connecting pads 120 and 125 may be electrically connected to the external connecting terminals 180 through the first redistribution patterns 130 and 160 and the electrode pads 175 of the package substrate 100.

The electrode pads 175 are exposed by the second insulating film 170 and may be electrically connected to the external connecting terminals 180. For example, the second insulating film 170 may include a silicon oxide film, a silicon nitride film or a silicon oxynitride film.

The first chip connecting pads 120 and 125 may include a first sub-chip connecting pad 120 and a second sub-chip connecting pad 125. The first chip connecting pads 120 and 125 may be connected to one or more other connecting pads through wires.

The package substrate 100 may include first redistribution patterns 130 and 160 that electrically connect the external connecting terminals 180 and the first chip connecting pads 120 and 125. The first redistribution patterns 130 and 160 may be, for example, but are not limited to, a metal such as copper (Cu), aluminum (Al), silver (Ag), gold (Au), tungsten (W), cobalt (Co), tin (Sn), nickel (Ni) and titanium (Ti), or an alloy thereof.

The first redistribution patterns 130 and 160 may include a first sub-redistribution pattern 160 surrounded by the base substrate 110, and a second sub-redistribution pattern 130 exposed on the upper side of the base substrate 110. Although the first sub-redistribution pattern 160 is shown as being a single layer in the drawings, the some example embodiments of the inventive concepts are not limited thereto, and the first sub-redistribution pattern 160 may have a structure in which the plurality of layers are stacked.

The first insulating film 150 may enclose both the upper side and the side face of the second sub-redistribution pattern 130. The first insulating film 150 may enclose the side faces of the first chip connecting pads 120 and 125. For example, the upper sides of the first chip connecting pads 120 and 125 may be exposed. For example, the first insulating film 150 may include a solder resist.

The first insulating film 150 may include a first trench 140 between the first sub-chip connecting pad 120 and the first semiconductor chip 200, and a second trench 145 between the second sub-chip connecting pad 125 and the first semiconductor chip 200. For example, the first insulating film 150 may define the first trench 140 and the second trench 145 therein. A detailed description of the first trench 140 and the second trench 145 will be provided below.

In some example embodiments, the first semiconductor chip 200 may include a plurality of second chip connecting pads 220 and 225 and a second redistribution pattern 230 on the upper side of the first substrate 210. The first substrate 210 may include for example a semiconductor element such as germanium (Ge), or a compound semiconductor such as silicon carbide (SiC), gallium arsenide (GaAs), indium arsenide (InAs), and indium phosphide (InP). The first substrate 210 may have a silicon-on-insulator (SOI) structure.

The second chip connecting pads 220 and 225 may include a third sub-chip connecting pad 220 and a fourth sub-chip connecting pad 225. The second chip connecting pads 220 and 225 may be connected to one or more other connecting pads through wires.

For example, the first sub-chip connecting pad 120 may be electrically connected to the third sub-chip connecting pad 220 by a third wire W3. The second sub-chip connecting pad 125 may be electrically connected to the fourth sub-chip connecting pad 225 by a fourth wire W4.

The first semiconductor chip 200 may include a second redistribution pattern 230 that electrically connects semiconductor elements inside the first semiconductor chip 200 and the second chip connecting pads 220 and 225. The second redistribution pattern 230 may be, for example, but is not limited to, a metal such as copper (Cu), aluminum (Al), silver (Ag), gold (Au), tungsten (W), cobalt (Al), tin (Sn), nickel (Ni) and titanium (Ti), or an alloy thereof.

The third insulating film 250 may enclose both the upper side and the side face of the second redistribution pattern 230. The third insulating film 250 may enclose the side faces of the second chip connecting pads 220 and 225. For example, the upper sides of the second chip connecting pads 220 and 225 may be exposed. For example, the third insulating film 250 may include, but is not limited to, an insulating material such as photosensitive polyimide (PSPI), silicon oxide, and silicon nitride.

The third insulating film 250 may include a third trench 240 between the third sub-chip connecting pad 220 and the second redistribution pattern 230, and a fourth trench 245 between the fourth sub-chip connecting pad 225 and the second redistribution pattern 230. For example, the third insulating film 250 may define the third trench 240 and the fourth trench 245 therein. A detailed description of the third trench 240 and the fourth trench 245 will be provided below.

In some example embodiments, the second semiconductor chip 300 may include a plurality of third chip connecting pads 320 and 325 and a third redistribution pattern 330 on the upper side of the second substrate 310. The second substrate 310 may include for example a semiconductor element such as germanium (Ge), or a compound semiconductor such as silicon carbide (SiC), gallium arsenide (GaAs), indium arsenide (InAs), and indium phosphide (InP). The second substrate 310 may have a silicon-on-insulator (SOI) structure.

The third chip connecting pads 320 and 325 may include a fifth sub-chip connecting pad 320 and a sixth sub-chip connecting pad 325. The third chip connecting pads 320 and 325 may be connected to one or more other connecting pads through wires.

For example, the third sub-chip connecting pad 220 may be electrically connected to the fifth sub-chip connecting pad 320 by a first wire W1. The fourth sub-chip connecting pad 225 may be electrically connected to the sixth sub-chip connecting pad 325 by a second wire W2.

The second semiconductor chip 300 may include a third redistribution pattern 330 that electrically connects semiconductor elements inside the second semiconductor chip 300 and the third chip connecting pads 320 and 325. The third redistribution pattern 330 may be, for example, but is not limited to, a metal such as copper (Cu), aluminum (Al), silver (Ag), gold (Au), tungsten (W), cobalt (Co), tin (Sn), nickel (Ni) and titanium (Ti), or an alloy thereof.

The fourth insulating film 350 may enclose both the upper side and the side face of the third redistribution pattern 330. The fourth insulating film 350 may cover the side faces of the third chip connecting pads 320 and 325. For example, the upper sides of the third chip connecting pads 320 and 325 may be exposed. For example, the fourth insulating film 350 may include, but is not limited to, an insulating material such as photosensitive polyimide (PSPI), silicon oxide and silicon nitride.

In some example embodiments, the mold layer 400 may cover the package substrate 100, the first semiconductor chip 200, the second semiconductor chip 300, and the first to fourth wires W1 to W4. The mold layer 400 may include a thermosetting resin, for example, an epoxy mold compound (EPOX).

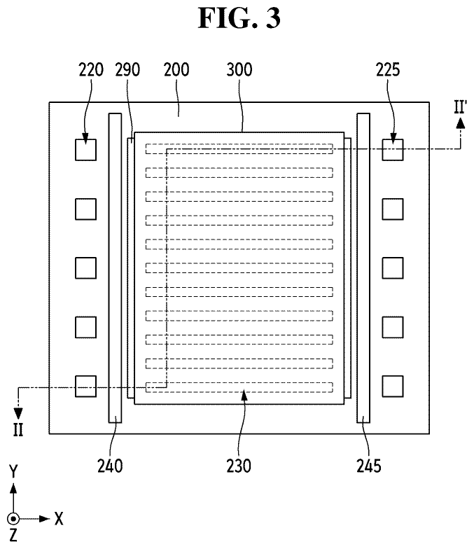

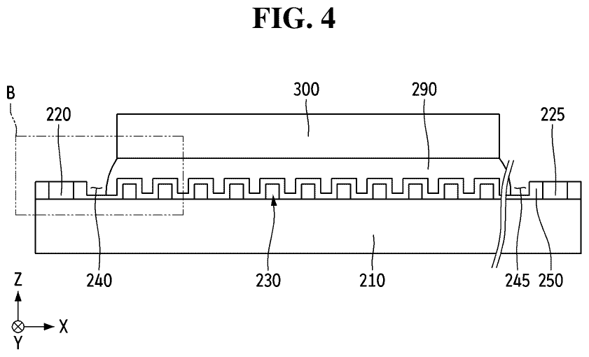

FIG. 3 is a top view showing only a partial configuration included in a region A of FIG. 2. FIG. 4 is a cross-sectional view showing a cross section taken along II-II′ of FIG. 3.

Referring to FIGS. 3 and 4, the plurality of third sub-chip connecting pads 220 may be disposed along a second direction (Y direction) on one side of the first semiconductor chip 200. The plurality of fourth sub-chip connecting pads 225 may be disposed along the second direction (Y direction) on the other side of the first semiconductor chip 200 opposite to the one side.

The plurality of second redistribution patterns 230 may be disposed between the second chip connecting pads 220 and 225. In the drawings, although the plurality of second redistribution patterns 230 are disposed in a parallel form along the second direction (Y direction), some example embodiments of the inventive concepts are not limited thereto, and the plurality of second redistribution patterns 230 may be disposed in an arbitrary form.

The third insulating film 250 may enclose both the upper side and the side face of the plurality of second redistribution patterns 230. The third insulating film 250 may enclose the side faces of the second chip connecting pads 220 and 225.

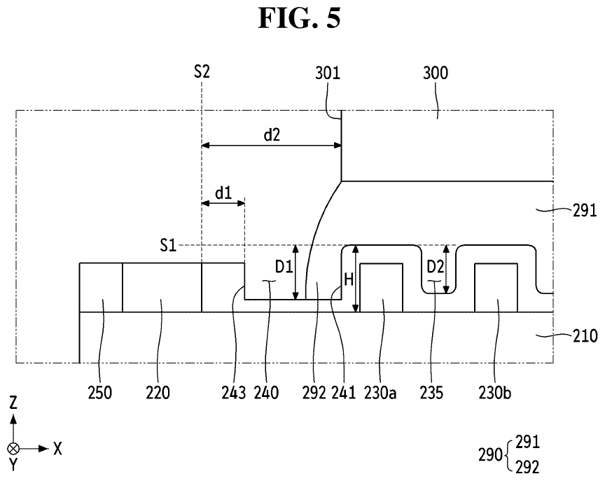

The third insulating film 250 may have a surface height that is not uniform depending on the shape of the plurality of second redistribution patterns 230 protruding from the upper side of the first semiconductor chip 200. Accordingly, a redistribution trench (235 of FIG. 5) may be formed. For example, the third insulating film 250 may define redistribution trenches 235 therein. A detailed description of the redistribution trenches 235 will be provided below in FIG. 5.

A second adhesive layer 290 is formed on the third insulating film 250, and the second semiconductor chip 300 may be attached onto the first semiconductor chip 200 by the second adhesive layer 290. The second adhesive layer 290 may be inserted between the redistribution trenches 235.

In some example embodiments, when the second semiconductor chip 300 is attached onto the second adhesive layer 290, the second adhesive layer 290 may spread outside the region to which the second semiconductor chip 300 is attached, depending on the viscosity of the second adhesive layer 290 or the pressure applied to the second semiconductor chip 300. The second adhesive layer 290 that spreads outside the region to which the second semiconductor chip 300 is attached may be in contact with the third trench 240 or the fourth trench 245. A detailed description thereof will be provided below.

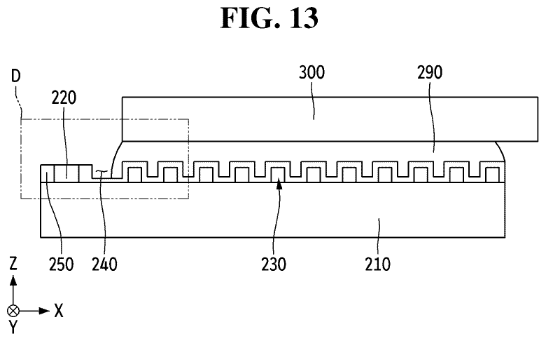

FIGS. 5 to 7 are enlarged views showing only a region B of FIG. 4 and a region D of FIG. 13.

Referring to FIG. 5, the third insulating film 250 may include a third trench 240 between the third sub-chip connecting pad 220 and the third sub-redistribution pattern 230a. The height of the third insulating film 250 may be a first height H. The first height H may be a height measured on the basis of a first reference line S1 that is the highest position in the third direction (Z direction).

A depth of the third trench 240 may be a first depth D1. The first depth D1 may be a depth measured along the third direction (Z direction) on the basis of the first reference line S1. The first depth D1 may be smaller than or equal to the first height H of the third insulating film 250.

The third trench 240 may include a first inner wall 241 and a second inner wall 243. The first inner wall 241 may be adjacent to the third sub-redistribution pattern 230a, and the second inner wall 243 may be adjacent to the third sub-chip connecting pad 220.

In some example embodiments, the second inner wall 243 may be farther from the center of the first semiconductor chip 200 than a first corner 301 of the second semiconductor chip 300. For example, when one side of the third sub-chip connecting pad 220 is set as a second reference line S2, a distance between the second reference line S2 and the second inner wall 243 may be a first distance d1. A distance between the second reference line S2 and the first corner 301 of the second semiconductor chip 300 may be a second distance d2. The first distance d1 may be smaller than the second distance d2.

The third insulating film 250 may also include a redistribution trench 235 between the third sub-redistribution pattern 230a and the third sub-redistribution pattern 230b.

In some example embodiments, the depth of the redistribution trench 235 may be a second depth D2. The second depth D2 may be smaller than or equal to the first depth D1. The second depth D2 may be a depth measured along a third direction (Z direction) on the basis of the first reference line S1.

In some example embodiments, the second adhesive layer 290 may exceed the attachment range of the second semiconductor chip 300. For example, the second adhesive layer 290 may include a first sub-adhesive layer 291 and a second sub-adhesive layer 292 that are configured integrally. The first sub-adhesive layer 291 may overlap the second semiconductor chip 300 in the third direction (Z direction). The second sub-adhesive layer 292 may not overlap the second semiconductor chip 300 in the third direction (Z direction). At least a part of the second sub-adhesive layer 292 may be in contact with the third trench 240.

By including the third trench 240 between the second semiconductor chip 300 attached on the first semiconductor chip 200 and the third sub-chip connecting pad 220, the second sub-adhesive layer 292 that exceeds the range which overlaps the second semiconductor chip 300 may be inserted and/or flow into the third trench 240. Therefore, it is possible to limit and/or prevent the third sub-chip connecting pad 220 from being contaminated by the bleeding-out phenomenon of the second sub-adhesive layer 292. As a result, it is possible to provide a semiconductor package having improved reliability.

In some example embodiments, the third trench 240 may have a shape in which the first inner wall 241 and the second inner wall 243 are parallel, and the bottom side is perpendicular to the first inner wall 241 or the second inner wall 243. However, some example embodiments of the inventive concepts are not limited thereto.

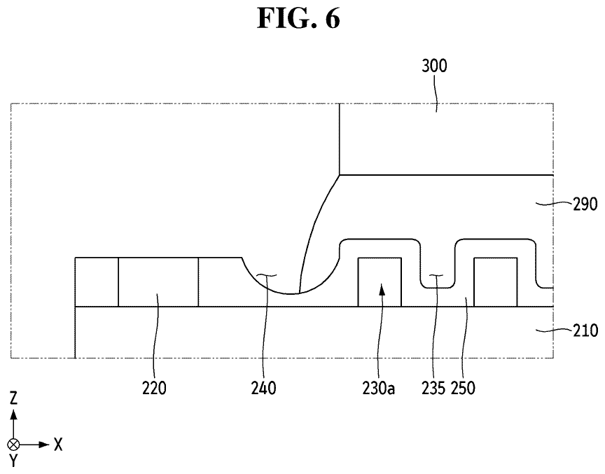

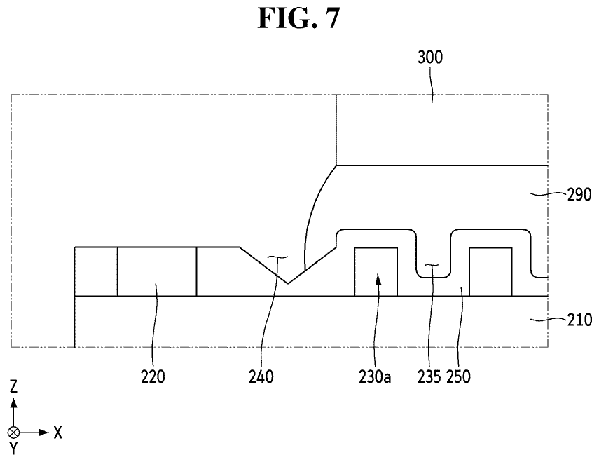

For example, referring to FIG. 6, the third trench 240 may have a semicircular shape in which the first inner wall 241, the second inner wall 243, and the bottom side have a radius of curvature. Alternatively, referring to FIG. 7, the third trench 240 may have a shape in which the first inner wall 241 and the second inner wall 243 come into contact with each other to form an apex. However, some example embodiments of the inventive concepts are not limited thereto.

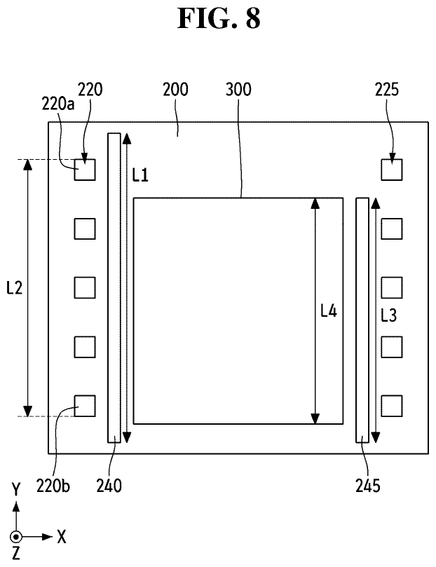

FIG. 8 is a top view showing only a partial configuration included in the region A of FIG. 2.

Referring to FIG. 8, in some example embodiments, the length of the third trench 240 may be a first length L1. The first length L1 may be a length of the third trench 240 measured along the second direction (Y direction).

The length of the plurality of third sub-chip connecting pads 220 may be a second length L2. For example, the third sub-chip connecting pad 220 may include a third sub-chip connecting pad 220a and a third sub-chip connecting pad 220b disposed at both ends in the second direction (Y direction). The second length L2 may be a distance between the third sub-chip connecting pad 220a and the third sub-chip connecting pad 220b.

In some example embodiments, the first length L1 may be greater than or equal to the second length L2. Accordingly, it is possible to limit and/or prevent the third sub-chip connecting pad 220 from being contaminated by the second adhesive layer 290 that exceeds the attachment range of the second semiconductor chip 300. Accordingly, it is possible to provide a semiconductor package having improved reliability.

In some example embodiments, the length of the fourth trench 245 may be a third length L3. The third length L3 may be a length of the fourth trench 245 measured along the second direction (Y direction).

The length of the second semiconductor chip 300 may be a fourth length L4. The fourth length L4 may be a length of the second semiconductor chip 300 measured along the second direction (Y direction).

In some example embodiments, the third length L3 may be greater than or equal to the fourth length L4. Accordingly, it is possible to limit and/or prevent the fourth sub-chip connecting pad 225 from being contaminated by the second adhesive layer 290 that exceeds the attachment range of the second semiconductor chip 300. Accordingly, it is possible to provide a semiconductor package having improved reliability.

For example, in summary, the length of the third trench 240 or the fourth trench 245 may be greater than or equal to the length of the second semiconductor chip 300 or the length of the adjacent chip connecting pads.

Although the third trench 240 and the fourth trench 245 are shown to have different lengths in the drawings, this corresponds to some example embodiments, and some other example embodiments of the inventive concepts are not limited thereto.

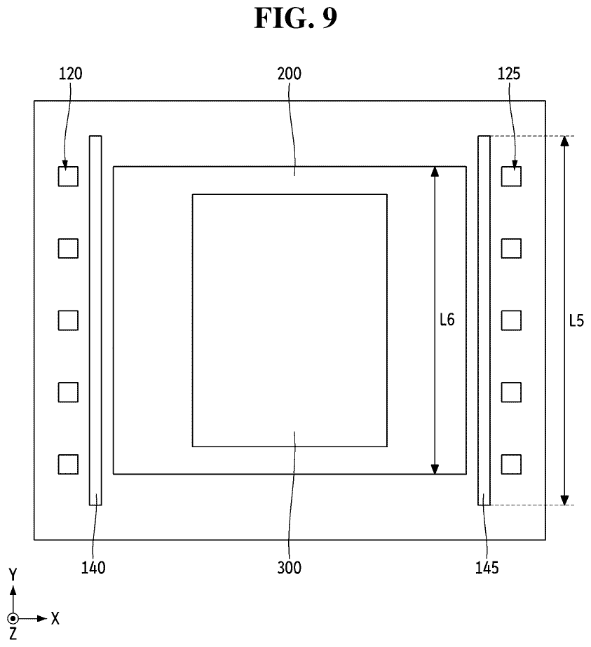

FIG. 9 is a top view for explaining only some configurations of FIG. 1 to explain a semiconductor package according to some example embodiments.

Referring to FIGS. 1 and 9, in some example embodiments, the length of the second trench 145 may be a fifth length L5. The fifth length L5 may be a length of the second trench 145 measured along the second direction (Y direction).

The length of the first semiconductor chip 200 may be a sixth length L6. The sixth length L6 may be the length of the first semiconductor chip 200 measured along the second direction (Y direction).

In some example embodiments, the fifth length L5 may be greater than or equal to the sixth length L6. Accordingly, it is possible to limit and/or prevent the second sub-chip connecting pad 125 from being contaminated by the first adhesive layer 190 that exceeds the attachment range of the first semiconductor chip 200. Accordingly, it is possible to provide a semiconductor package having improved reliability.

The length of the first trench 140 may also be determined in a similar manner to the length of the second trench 145.

For example, in summary, the length of the first trench 140 or the second trench 145 may be greater than or equal to the length of the first semiconductor chip 200. Alternatively, in a similar manner to that described in FIG. 8, the length of the first trench 140 or the second trench 145 may be greater than or equal to the length of the adjacent chip connecting pad.

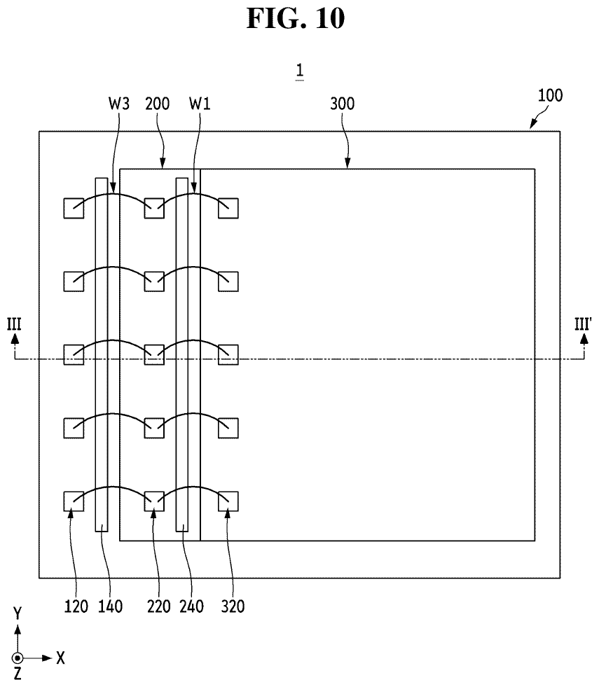

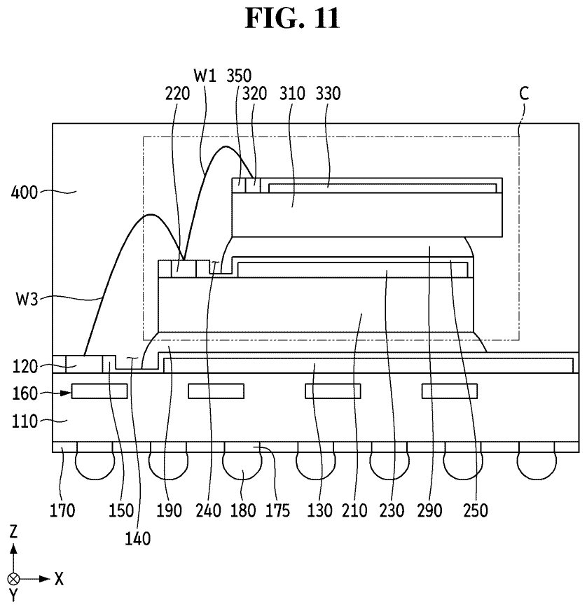

FIG. 10 is a top view for explaining a semiconductor package according to some example embodiments of the inventive concepts. FIG. 11 is a cross-sectional view showing a cross section taken along III-III′ of FIG. 10. FIGS. 10 and 11 are similar to the configuration of the semiconductor package described in FIGS. 1 and 2, and therefore a description of the same configurations will be omitted, and differences will be mainly described.

Referring to FIGS. 10 and 11, in some example embodiments, the semiconductor package 1 may include a package substrate 100, a first semiconductor chip 200, a second semiconductor chip 300, and a mold layer 400. The first semiconductor chip 200 and the second semiconductor chip 300 may be stacked in sequence on the package substrate 100.

In some example embodiments, the second semiconductor chip 300 may be stacked to be shifted by a desired (and/or alternatively predetermined) distance in the first direction (e.g., an X or horizontal direction) so that the upper side of the first semiconductor chip 200 is at least partially exposed.

In some example embodiments, the size of the second semiconductor chip 300 may be the same as the size of the first semiconductor chip 200.

The first chip connecting pad 120 may be connected to one or more other connecting pads through wires.

The first insulating film 150 may include a first trench 140 between the first chip connecting pad 120 and the second sub-redistribution pattern 130. A detailed description of the first trench 140 will be provided below.

In some example embodiments, the first semiconductor chip 200 may include a plurality of second chip connecting pads 220 and a second redistribution pattern 230 on the upper side of the first substrate 210.

The second chip connecting pads 220 may be connected to one or more other connecting pads through wires.

The third insulating film 250 may include a second trench 240 between the second chip connecting pad 220 and the second redistribution pattern 230. A detailed description of the second trench 240 will be provided below.

In some example embodiments, the second semiconductor chip 300 may include a plurality of third chip connecting pads 320 and a third redistribution pattern 330 on the upper side of the second substrate 310.

The third chip connecting pads 320 may be connected to one or more other connecting pads through wires.

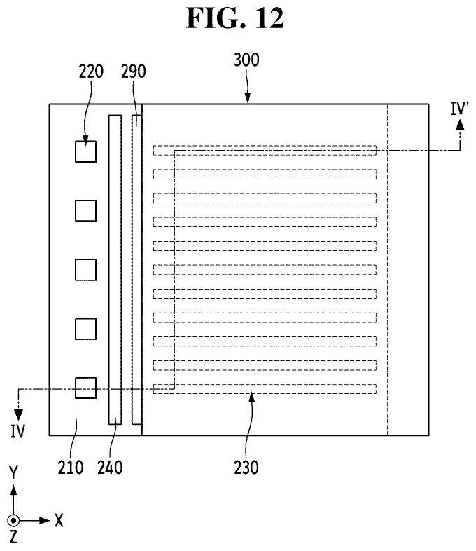

FIG. 12 is a top view showing only a partial configuration included in the region C of FIG. 11. FIG. 13 is a cross-sectional view showing a cross section taken along IV-IV′ of FIG. 12. FIGS. 12 and 13 are similar to the configuration of the semiconductor package described in FIGS. 3 and 4, and therefore the description of the same configuration will be omitted, and the differences will be mainly described.

Referring to FIGS. 12 and 13, the plurality of second chip connecting pads 220 may be disposed along the second direction (Y direction) on one side of the first semiconductor chip 200.

The plurality of second redistribution patterns 230 may be disposed to be spaced apart from the second chip connecting pads 220 in the first direction (X direction). Although the plurality of second redistribution patterns 230 are disposed in a parallel form along the second direction (Y direction) in the drawings, some example embodiments of the inventive concepts are not limited thereto, and the plurality of second redistribution patterns 230 may be disposed in an arbitrary form.

The third insulating film 250 may enclose both the upper side and the side face of the plurality of second redistribution patterns 230. The third insulating film 250 may enclose the side face of the second chip connecting pad 220. The third insulating film 250 may include a second trench 240 between the second chip connecting pad 220 and the second redistribution pattern 230.

The third insulating film 250 may have a surface height that is not constant depending on the shape of the plurality of second redistribution patterns 230 protruding from the upper side of the first semiconductor chip 200. Accordingly, a redistribution trench (235 of FIG. 5) may be formed.

In some example embodiments, a second adhesive layer 290 may be formed on the third insulating film 250, and the second semiconductor chip 300 may be attached onto the first semiconductor chip 200 by the second adhesive layer 290. The second adhesive layer 290 may be inserted between the redistribution trenches 235.

In some example embodiments, when the second semiconductor chip 300 is attached onto the second adhesive layer 290, the second adhesive layer 290 may spread outside the region to which the second semiconductor chip 300 is attached, depending on the viscosity of the second adhesive layer 290 or the pressure applied to the second semiconductor chip 300. The second adhesive layer 290, which spreads outside the region to which the second semiconductor chip 300 is attached, may be in contact with the second trench 240.

Referring to FIG. 5 again, the third insulating film 250 may include a second trench 240 between the second chip connecting pad 220 and the third sub-redistribution pattern 230a. The height of the third insulating film 250 may be a first height H. The first height H may be a height measured on the basis of the first reference line S1, which is the highest position in the third direction (Z direction).

The depth of the second trench 240 may be a first depth D1. The first depth D1 may be smaller than or equal to the height of the third insulating film 250. The first depth D1 may be a depth measured along the third direction (Z direction) on the basis of the first reference line S1.

The second trench 240 may include a first inner wall 241 and a second inner wall 243. The first inner wall 241 may be adjacent to the second redistribution pattern 230, and the second inner wall 243 may be adjacent to the second chip connecting pad 220.

In some example embodiments, the second inner wall 243 may be farther from the center of the first semiconductor chip 200 than the first corner 301 of the second semiconductor chip 300. For example, when one side of the second chip connecting pad 220 is set as a second reference line S2, a distance between the second reference line S2 and the second inner wall 243 may be a first distance d1. A distance between the second reference line S2 and the first corner 301 of the second semiconductor chip 300 may be a second distance d2. The first distance d1 may be smaller than the second distance d2.

The third insulating film 250 may also include a redistribution trench 235 between the third sub-redistribution pattern 230a and the third sub-redistribution pattern 230b.

In some example embodiments, a depth of the redistribution trench 235 may be a second depth D2. The second depth D2 may be smaller than or equal to the first depth D1. The second depth D2 may be a depth measured along the third direction (Z direction) on the basis of the first reference line S1.

In some example embodiments, the second adhesive layer 290 may exceed the attachment range of the second semiconductor chip 300. For example, the second adhesive layer 290 may include a first sub-adhesive layer 291 and a second sub-adhesive layer 292. The first sub-adhesive layer 291 may overlap the second semiconductor chip 300 in the third direction (Z direction). The second sub-adhesive layer 292 may not overlap the second semiconductor chip 300 in the third direction (Z direction). At least a part of the second sub-adhesive layer 292 may be in contact with the third trench 240.

By including the second trench 240 between the second semiconductor chip 300 attached on the first semiconductor chip 200 and the third sub-chip connecting pad 220, the second sub-adhesive layer 292 that exceeds the range which overlaps the second semiconductor chip 300 may be inserted into and/or flow into the second trench 240. Therefore, it is possible to limit and/or prevent the second chip connecting pad 220 from being contaminated by the bleeding-out phenomenon of the second sub-adhesive layer 292. Accordingly, it is possible to provide a semiconductor package having improved reliability.

In some example embodiments, the second trench 240 may have a shape in which the first inner wall 241 and the second inner wall 243 are parallel, and the bottom side is perpendicular to the first inner wall 241 or the second inner wall 243. However, some example embodiments of the inventive concepts are not limited thereto.

For example, referring to FIG. 6, the second trench 240 may have a shape in which the first inner wall 241, the second inner wall 243, and the bottom side have different radii of curvature from each other. Alternatively, referring to FIG. 7, the second trench 240 may have a shape in which the first inner wall 241 and the second inner wall 243 come into contact with each other to form an apex. However, some example embodiments of the inventive concepts are not limited thereto.

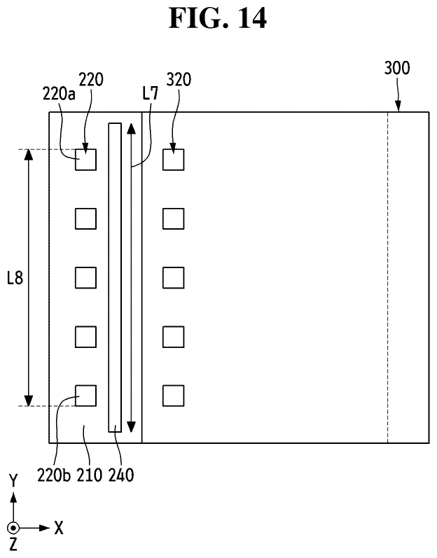

FIG. 14 is a top view showing only a partial configuration included in a region C of FIG. 11.

Referring to FIG. 14, in some example embodiments, the length of the second trench 240 may be a seventh length L7. The seventh length L7 may be the length of the second trench 240 measured along the second direction (Y direction).

The length of the plurality of second chip connecting pads 220 may be an eighth length L8. For example, the second chip connecting pad 220 may include a second chip connecting pad 220a and a second chip connecting pad 220b that are disposed at both ends in the second direction (Y direction). The eighth length L8 may be a distance between the second chip connecting pad 220a and the second chip connecting pad 220b.

In some example embodiments, the seventh length L7 may be greater than or equal to the eighth length L8. Accordingly, it is possible to limit and/or prevent the third sub-chip connecting pad 220 from being contaminated by the second adhesive layer 290 that exceeds the attachment range of the second semiconductor chip 300. Accordingly, it is possible to provide a semiconductor package having improved reliability.

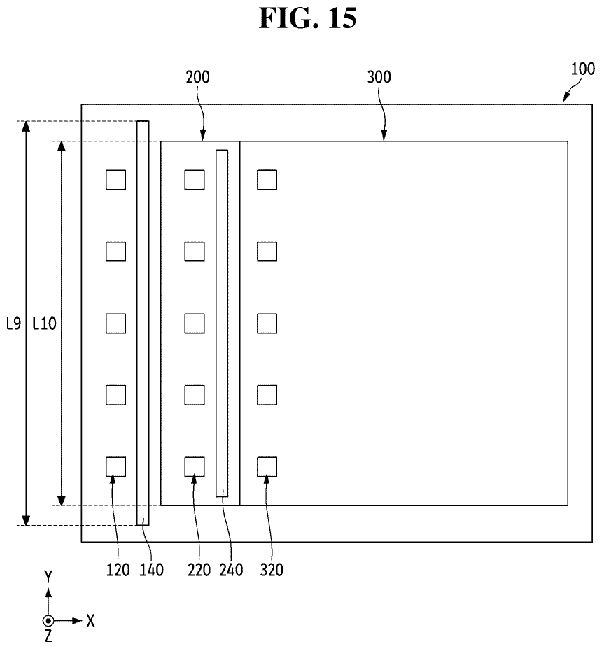

FIG. 15 is a top view for explaining only a partial configuration of FIG. 10 to explain the semiconductor package according to some example embodiments of the inventive concepts.

Referring to FIGS. 10 and 15, in some example embodiments, the length of the first trench 140 may be a ninth length L9. The ninth length L9 may be the length of the first trench 140 measured along the second direction (Y direction).

The length of the first semiconductor chip 200 may be a tenth length L10. The tenth length L10 may be a length of the first semiconductor chip 200 measured along the second direction (Y direction).

In some example embodiments, the ninth length L9 may be greater than or equal to the tenth length L10. Accordingly, it is possible to limit and/or prevent the first chip connecting pad 120 from being contaminated by the first adhesive layer 190 that exceeds the attachment range of the first semiconductor chip 200. Accordingly, it is possible to provide a semiconductor package having improved reliability.

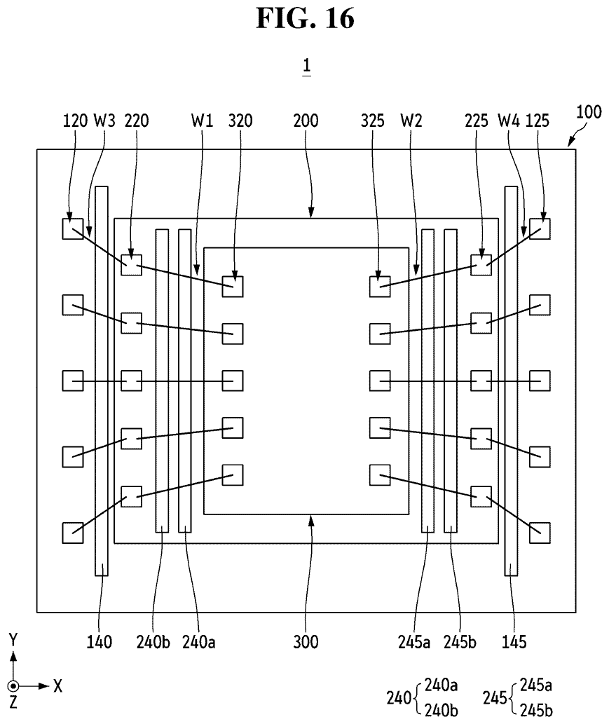

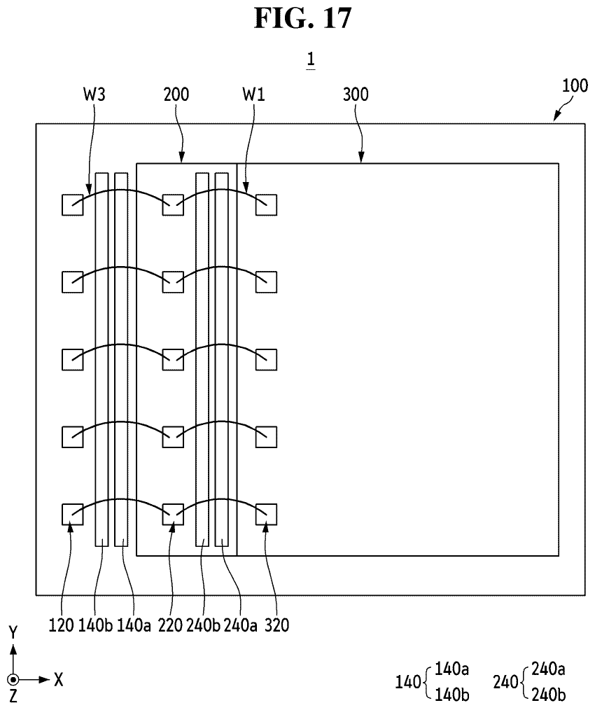

FIGS. 16 and 17 are top views for explaining a semiconductor package according to some embodiments of the inventive concepts. FIG. 16 is similar to the configuration of the semiconductor package described in FIGS. 1 and 2, and therefore a description of the same configuration will be omitted, and differences will be mainly described. FIG. 17 is similar to the configuration of the semiconductor package described in FIGS. 10 and 11, and therefore the description of the same configuration will be omitted and differences will be mainly described.

Referring to FIG. 16, the first insulating film 150 may include a first trench 140 between the first sub-chip connecting pad 120 and the first semiconductor chip 200. The third insulating film 250 may include a third trench 240 between the third sub-chip connecting pad 220 and the second semiconductor chip 300, and a fourth trench 245 between the fourth sub-chip connecting pad 225 and the second semiconductor chip 300.

The third trench 240 may include a first sub-trench 240a and a second sub-trench 240b that are disposed side by side along the first direction (X direction).

The fourth trench 245 may include a third sub-trench 245a and a fourth sub-trench 245b that are disposed side by side along the first direction.

The first trench 140 is included between the first semiconductor chip 200 and the first sub-chip connecting pad 120, the second trench 145 is included between the first semiconductor chip 200 and the second sub-chip connecting pad 125, the third trench 240 is included between the second semiconductor chip 300 and the third sub-chip connecting pad 220, and the fourth trench 245 is included between the second semiconductor chip 300 and the fourth sub-chip connecting pad 225. Accordingly, the first adhesive layer 190 that exceeds the range which overlaps the first semiconductor chip 200, and the second adhesive layer 290 that exceeds the range which overlaps the second semiconductor chip 300 may be inserted into and/or flow into the first trench 140, the second trench 145, the third trench 240 and the fourth trench 245. Accordingly, the first chip connecting pads 120 and 125 and the second chip connecting pads 220 and 225 may be limited and/or prevented from being contaminated. Accordingly, it is possible to provide a semiconductor package having improved reliability.

Referring to FIG. 17, the first insulating film 150 may include a first trench 140 between the first sub-chip connecting pad 120 and the first semiconductor chip 200. The third insulating film 250 may include a second trench 240 between the second chip connecting pads 220 and 225 and the second semiconductor chip 300.

The first trench 140 may include a first sub-trench 140a and a second sub-trench 140b that are disposed side by side along the first direction (X direction).

The second trench 240 may include a third sub-trench 240a and a fourth sub-trench 240b that are disposed side by side along the first direction.

The first trench 140 is included between the first semiconductor chip 200 and the first chip connecting pad 120, and the second trench 240 is included between the second semiconductor chip 300 and the second chip connecting pad 220. Accordingly, the first adhesive layer 190 that exceeds the range which overlaps the first semiconductor chip 200, and the second adhesive layer 290 that exceeds the range which overlaps the second semiconductor chip 300 may be inserted into and/or flow into the first trench 140 and the second trench 240. Therefore, the first chip connecting pad 120 and the second chip connecting pad 220 may be limited and/or prevented from being contaminated. Accordingly, it is possible to provide a semiconductor package having improved reliability.

The above-mentioned semiconductor package 1 may include semiconductor elements such as logic elements and memory elements. The semiconductor package 1 may include, for example, logic elements such as a central processing unit (CPU, MPU) and an application processor (AP), volatile memory devices such as a SRAM device and a DRAM device, and non-volatile memory devices such as a flash memory device, a PRAM device, a MRAM device, and a RRAM device.

Although some example embodiments of the inventive concepts have been described above with reference to the accompanying drawings, the inventive concepts are not limited to the above some example embodiments, and may be fabricated in various different forms. Those skilled in the art will appreciate that the inventive concepts may be embodied in other specific forms without changing the technical spirit or essential features of the inventive concepts. Accordingly, the above-described embodiments should be understood in all respects as illustrative and not restrictive.

What is claimed is:

1. A semiconductor package comprising:
a package substrate;
a first semiconductor chip on the package substrate;
a second semiconductor chip on the first semiconductor chip; and
an adhesive layer between the first semiconductor chip and the second semiconductor chip,
wherein the first semiconductor chip includes
a plurality of redistribution patterns on a first surface of the first semiconductor chip,
a plurality of chip connecting pads, and
an insulating layer enclosing the plurality of redistribution patterns and the plurality of chip connecting pads, and
wherein the insulating layer defines at least one trench therein between the plurality of redistribution patterns and the plurality of chip connecting pads, the plurality of redistribution patterns are adjacent to the plurality of chip connecting pads, and the plurality of chip connecting pads are electrically connected to the second semiconductor chip through wires.

2. The semiconductor package of claim 1, wherein
a depth of the at least one trench is less than or equal to a height of the insulating layer.

3. The semiconductor package of claim 1, wherein
a redistribution pattern from among the plurality of redistribution patterns includes a first sub-redistribution pattern and a second sub-redistribution pattern adjacent to each other, and
the insulating layer defines a redistribution trench therein between the first sub-redistribution pattern and the second sub-redistribution pattern.

4. The semiconductor package of claim 3, wherein a depth of the at least one trench is greater than a depth of the redistribution trench.

5. The semiconductor package of claim 1, wherein
the at least one trench includes a single trench,
the single trench includes a first inner wall and a second inner wall,
the first inner wall is adjacent to the plurality of redistribution patterns,
the second inner wall is adjacent to the plurality of chip connecting pads, and
a distance between the second inner wall and the plurality of chip connecting pads in a horizontal direction is less than a distance between a first corner of the second semiconductor chip and the plurality of chip connecting pads.

6. The semiconductor package of claim 1, wherein
the plurality of chip connecting pads include a first sub-chip connecting pad and a second sub-chip connecting pad that are respectively at opposite ends of the plurality of redistribution patterns, and
the at least one trench includes
a first trench between the plurality of redistribution patterns and the first sub-chip connecting pad, and
a second trench between the plurality of redistribution patterns and the second sub-chip connecting pad.

7. The semiconductor package of claim 1, wherein
the adhesive layer includes a first sub-adhesive layer that overlaps the second semiconductor chip in a vertical direction, and a second sub-adhesive layer that does not overlap the second semiconductor chip in the vertical direction,
the first sub-adhesive layer and the second sub-adhesive layer are integral, and
at least a part of the second sub-adhesive layer contacts the at least one trench.

8. The semiconductor package of claim 1, wherein
a length of the at least one trench in a horizontal direction is greater than or equal to a length of the second semiconductor chip in the horizontal direction.

9. The semiconductor package of claim 1, wherein
the plurality of chip connecting pads include a first chip connecting pad adjacent to a first corner of the first semiconductor chip, and a second chip connecting pad adjacent to a second corner of the first semiconductor chip opposite to the first corner, and
a length of the at least one trench in a horizontal direction is greater than or equal to a distance between the first chip connecting pad and the second chip connecting pad in the horizontal direction.

10. The semiconductor package of claim 1, further comprising:
a second adhesive layer between the package substrate and the first semiconductor chip,
wherein the package substrate includes
a second redistribution pattern on the first surface of the package substrate,
a plurality of second chip connecting pads, and
a second insulating layer enclosing the second redistribution pattern and the plurality of second chip connecting pads, and
wherein the second insulating layer defines a second trench therein between the second redistribution pattern and the plurality of second chip connecting pads, the second redistribution pattern is adjacent the plurality of second chip connecting pads, and the plurality of second chip connecting pads are electrically connected to the first semiconductor chip through second wires.

11. The semiconductor package of claim 10, wherein
a length of the second trench in a horizontal direction is greater than or equal to a length of the first semiconductor chip in the horizontal direction.

12. The semiconductor package of claim 1, further comprising:
a mold layer enclosing the package substrate, the first semiconductor chip, the second semiconductor chip, and the adhesive layer.

13. A semiconductor package comprising:
a package substrate;
a first semiconductor chip on the package substrate;
a second semiconductor chip on the first semiconductor chip;
an adhesive layer between the first semiconductor chip and the second semiconductor chip; and
a mold layer enclosing the package substrate, the first semiconductor chip, the second semiconductor chip, and the adhesive layer,
wherein the first semiconductor chip includes
a plurality of redistribution patterns on a first surface of the first semiconductor chip,
a plurality of chip connecting pads, and
an insulating layer enclosing the plurality of redistribution patterns and the plurality of chip connecting pads, the plurality of chip connecting pads being electrically connected to the second semiconductor chip through wires, wherein the insulating layer includes
a first insulating layer enclosing side faces of the plurality of chip connecting pads, and
a second insulating layer enclosing the plurality of redistribution patterns, and wherein
the first insulating layer defines a trench therein between the plurality of chip connecting pads and the plurality of redistribution patterns,
the second insulating layer defines a redistribution trench between chip connecting pads of the plurality of chip connecting pads, and
a depth of the trench is greater than a depth of the redistribution trench.

14. The semiconductor package of claim 13, wherein
the trench includes a first inner wall and a second inner wall,
the first inner wall is adjacent to the plurality of redistribution patterns,
the second inner wall is adjacent to the plurality of chip connecting pads, and
a distance between the second inner wall and the plurality of chip connecting pads in a horizontal direction is smaller than a distance between a first corner of the second semiconductor chip and the plurality of chip connecting pads.

15. The semiconductor package of claim 13, wherein
the plurality of chip connecting pads include a first sub-chip connecting pad and a second sub-chip connecting pad that are respectively at opposite ends of the plurality of redistribution patterns, and
the trench includes
a plurality of first trenches between the plurality of redistribution patterns and the first sub-chip connecting pad, and
a plurality of second trenches between the plurality of redistribution patterns and the second sub-chip connecting pad.

16. The semiconductor package of claim 13, wherein
the adhesive layer includes a first sub-adhesive layer that overlaps the second semiconductor chip in a vertical direction, and a second sub-adhesive layer that does not overlap the second semiconductor chip in the vertical direction,
the first sub-adhesive layer and the second sub-adhesive layer are integral, and
at least a part of the second sub-adhesive layer contacts the trench.

17. The semiconductor package of claim 13, wherein
a length of the trench in a horizontal direction is greater than or equal to a length of the second semiconductor chip in the horizontal direction.

18. The semiconductor package of claim 13, wherein
the plurality of chip connecting pads include a first chip connecting pad adjacent to a first corner of the first semiconductor chip, and a second chip connecting pad adjacent to a second corner of the first semiconductor chip opposite to the first corner, and
a length of the trench in a horizontal direction is greater than or equal to a distance between the first chip connecting pad and the second chip connecting pad in the horizontal direction.

19. The semiconductor package of claim 13, further comprising:
a second adhesive layer between the package substrate and the first semiconductor chip,
wherein the package substrate includes
a second redistribution pattern on a first surface of the package substrate,
a plurality of second chip connecting pads, and
a second insulating layer enclosing the second redistribution pattern and the plurality of second chip connecting pads, and
wherein the second insulating layer defines a third trench therein between the second redistribution pattern and the plurality of second chip connecting pads, the second redistribution pattern is adjacent the plurality of second chip connecting pads, and the plurality of second chip connecting pads are electrically connected to the first semiconductor chip through second wires.

20. A semiconductor package comprising:
a package substrate;
a first semiconductor chip on the package substrate;
a second semiconductor chip on the first semiconductor chip;
an adhesive layer between the first semiconductor chip and the second semiconductor chip; and
a mold layer enclosing the package substrate, the first semiconductor chip, the second semiconductor chip, and the adhesive layer,
wherein the first semiconductor chip includes
a plurality of redistribution patterns on a first surface of the first semiconductor chip,
a plurality of chip connecting pads, and
an insulating layer enclosing the plurality of redistribution patterns and the plurality of chip connecting pads, the plurality of chip connecting pads being electrically connected to the second semiconductor chip through wires,
wherein the insulating layer includes
a first insulating layer enclosing side faces of the plurality of chip connecting pads, and
a second insulating layer enclosing the plurality of redistribution patterns, and
wherein
the first insulating layer defines a trench between the plurality of chip connecting pads and the plurality of redistribution patterns,
the second insulating layer defines a redistribution trench between chip connecting pads of the plurality of chip connecting pads,
a depth of the trench is greater than a depth of the redistribution trench, and
a length of the trench in a horizontal direction is greater than or equal to a length of the second semiconductor chip in the horizontal direction,
the adhesive layer includes a first sub-adhesive layer overlapping the second semiconductor chip in a vertical direction, and a second sub-adhesive layer not overlapping the second semiconductor chip in the vertical direction,
the first sub-adhesive layer and the second sub-adhesive layer are integral, and
at least a part of the second sub-adhesive layer contacts the trench.
